(19) United States
(12) Patent Application Publication
(10) Pub. No.: US 2008/0233671 A1
(43) Pub. Date: Sep. 25, 2008

(54) Method of fabricating GaN LED

(75) Inventors: Mitch M. C. Chou, Chiayi City (TW); Jih-Jen Wu, Kaohsiung City (TW); Wen-Ching Hsu, Hsinchu City (TW)

Correspondence Address: TROXELL LAW OFFICE PLLC;SUITE 1404, 5205 LEESBURG PIKE, FALLS CHURCH, VA, 22041, US

(73) Assignees: National Sun Yat-sen University, Kaohsiung City (TW); Sino American Silicon Products Inc., Hsinchu City (TW)

(21) Appl. No.: 11/808,565

(22) Filed: Jun. 11, 2007

(30) Foreign Application Priority Data
Mar. 22, 2007 (TW) 096110015

(51) Int. Cl. H01L 21/02

(52) U.S. Cl. 438/47; 257/E21.09

(57) ABSTRACT

A light emitting diode (LED) is made. The LED had a LiAlO₂ substrate and a GaN layer. Between them, there is a zinc oxide (ZnO) layer. Because GaN and ZnO have a similar. Wurtzite structure, GaN can easily grow on ZnO. By using the ZnO layer, the GaN layer is successfully grown as a single crystal thin film on the LiAlO₂ substrate. Thus, GaN defect density is reduced and lattice match is obtained to have a good crystal interface quality and an enhanced light emitting efficiency of a device thus made.

### FIELD OF THE INVENTION

The present invention relates to fabricating a gallium nitride (GaN) light emitting diode (LED); more particularly, relates to using a zinc oxide (ZnO) buffer layer to successfully grow a GaN nucleus-site layer as a single crystal thin film on a lithium aluminum oxide (LiAlO₂) substrate for reducing GaN defect density and for further obtaining lattice match to have a good crystal interface quality and an enhanced light emitting efficiency of a device thus made.

### DESCRIPTION OF THE RELATED ARTS

A traditional LED usually uses a sapphire substrate to grow GaN. As shown in FIG. 7 and FIG. 8, a sapphire substrate 31 is obtained to grow a GaN multiple quantum well (MQW) 32 and then a p-side electrode layer 33. And then an n-side electrode layer 34 is grown at another side on the GaN MQW 32. Thus, a LED is made.

However, its electroluminescence spectrum is controlled by the quantum wells near the p-side electrode layer 33, emitting a non-uniformed white light. Because holes move much slower than electrons, light emitting quantum wells gather around the p-side electrode layer 33 and so the other quantum wells have a bad light emitting efficiency.

And because the GaN MQW 33 and the sapphire substrate 31 have a lattice mismatch in between, equilibrium lattice positions of the GaN MQW 33 is not good, as shown in FIG. 9. Thus, crystal interface quality become bad and quality of a device thus made is degraded.

In the other hand, another prior art uses a ZnO substrate directly to grow a GaN layer. Although ZnO and GaN have a similar structure for GaN to easily grow on ZnO with a high quality, ZnO is expansive especially when a whole substrate of ZnO is more than what is in need. And such a situation makes mass production difficult. Hence, the prior arts do not fulfill all users' requests on actual use.

### SUMMARY OF THE INVENTION

The main purpose of the present invention is to use a ZnO buffer layer to successfully grow a GaN nucleus-site layer as a single crystal thin film on a LiAlO₂ substrate for reducing GaN defect density and for further obtaining lattice match to have a good crystal interface quality and an enhanced light emitting efficiency of a device thus made

To achieve the above purpose, the present invention is a method of fabricating a GaN LED, comprising steps of: (a) obtaining a substrate of LiAlO₂; (b) growing a GaN nucleus-site layer after growing a ZnO buffer layer on the LiAlO₂ substrate to obtain a structure of GaN/ZnO/LiAlO2 to grow a layer of multiple quantum well (MQW) and a first metal electrode layer; (c) removing the LiAlO₂ substrate and the ZnO buffer layer through etching; and (d) growing a second metal electrode layer beneath the GaN nucleus-site layer. Accordingly, a novel method of fabricating a GaN LED is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the flow view showing the preferred embodiment according to the present invention;

FIG. 2 is the view showing the LiAlO₂ substrate;

FIG. 3 is the view showing the structure after the series of epitaxy;

FIG. 4 is the view showing the structure after etching the LiAlO₂ substrate and the ZnO buffer layer;

FIG. 5 is the view showing the LED;

FIG. 6 is the view showing the matched lattice;

FIG. 7 is the view of the prior art growing the MQW and the p-side electrode layer on the substrate;

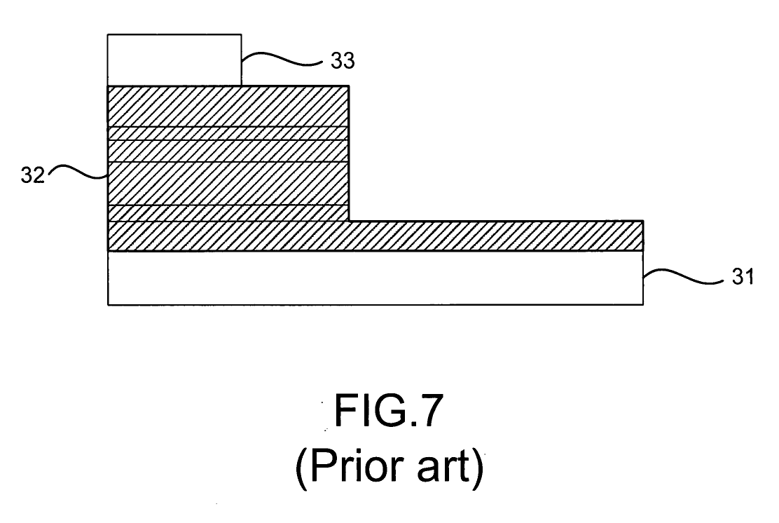

FIG. 8 is the view of the LED prior art; and

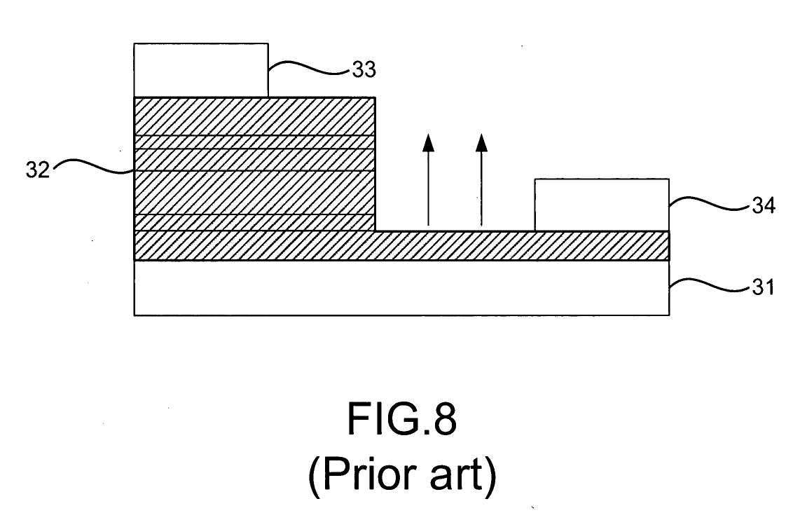

FIG. 9 is the view of the mismatched lattices of the prior art.

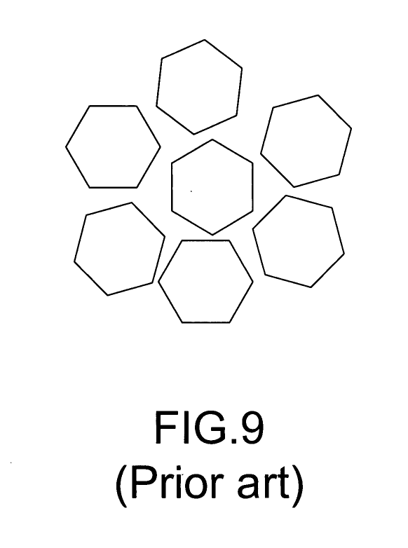

### DESCRIPTION OF THE PREFERRED EMBODIMENT

The following description of the preferred embodiment is provided to understand the features and the structures of the present invention.

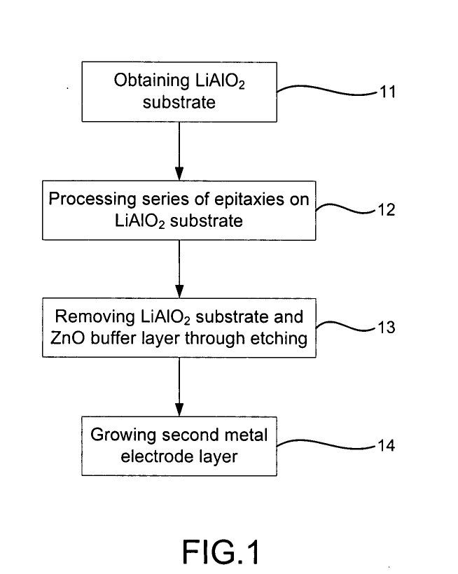

Please refer to FIG. 1 to FIG. 5, which are a flow view showing a preferred embodiment according to the present invention; a view showing a LiAlO₂ substrate; a view showing a structure after a series of epitaxy; a view showing a structure after etching the LiAlO₂ substrate and a ZnO buffer layer; and a view showing a LED. As shown in the figures, the present invention is a method of fabricating a gallium nitride (GaN) light emitting diode (LED), comprising the following steps:

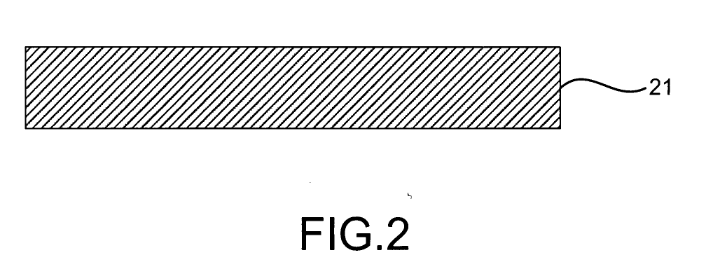

(a) Obtaining a LiAlO₂ substrate 11: As shown in FIG. 2, a substrate of lithium aluminum oxide (LiAlO₂) 21 is obtained. The substrate can further be a substrate of lithium gallium oxide (LiGaO₂), lithium silicon oxide (Li₂SiO₃), lithium germanium oxide (LiGeO₃), sodium aluminum oxide (NaAlO₂), sodium germanium oxide (Na₂GeO₃), sodium silicon oxide (Na₂SiO₃), lithium phosphor oxide (Li₃PO₄), lithium arsenic oxide (Li₃AsO₄), lithium vanadium oxide (Li₃VO₄), lithium magnesium germanium oxide (Li₂MgGeO₄), lithium zinc germanium oxide (Li₂ZnGeO₄), lithium cadmium germanium oxide (Li₂CdGeO₄), lithium magnesium silicon oxide (Li₂MgSiO₄), lithium zinc silicon oxide (Li₂ZnSiO₄), lithium cadmium silicon oxide (Li₂CdSiO₄), sodium magnesium germanium oxide (Na₂MgGeO₄), sodium zinc germanium oxide (Na₂ZnGeO₄) or sodium zinc silicon oxide (Na₂ZnSiO₄).

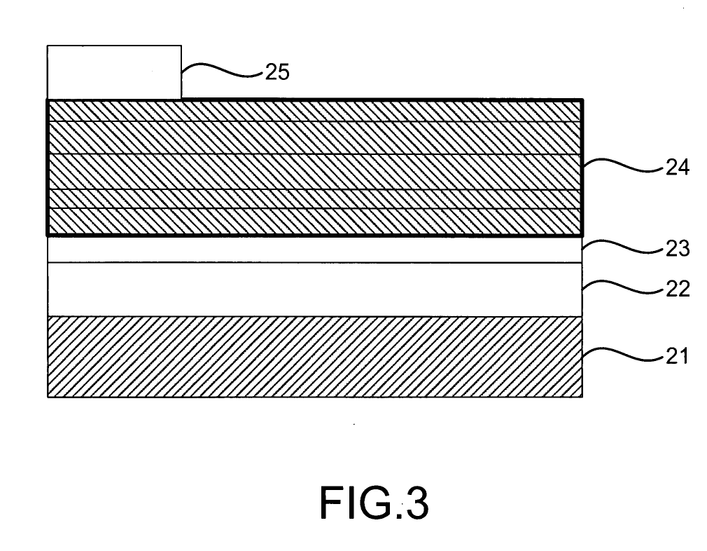

(b) Processing a series of epitaxies on the LiAlO₂ substrate 12: As shown in FIG. 3, a series of epitaxies are processed to upwardly grow a zinc oxide (ZnO) buffer layer 22, which is a single crystal thin film on the LiAlO₂ substrate 21, followed with a gallium nitride (GaN) nucleus-site layer 23 grown on the ZnO buffer layer 22. Thus, a structure of GaN/ZnO/LiAlO₂ is obtained to be grown with a layer of multiple quantum well (MQW) 24 and a first metal electrode layer 25, where the MQW layer 24 comprises at least one quantum well having a different well width and a different barrier width.

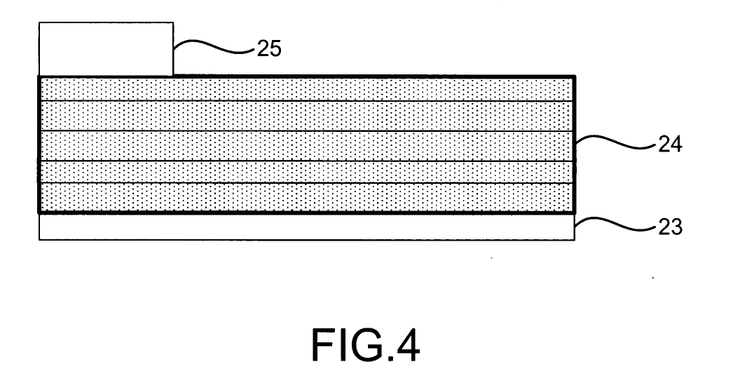

(c) Removing the LiAlO₂ substrate and the ZnO buffer layer through etching 13: As shown in FIG. 4, the epitaxial structure obtained through the above steps is soaked in an acid solution to remove the LiAlO₂ substrate 21 and the ZnO buffer layer 22 by etching, where the acid solution is a nitric acid solution, a hydrofluoric acid solution or an acetic acid solution.

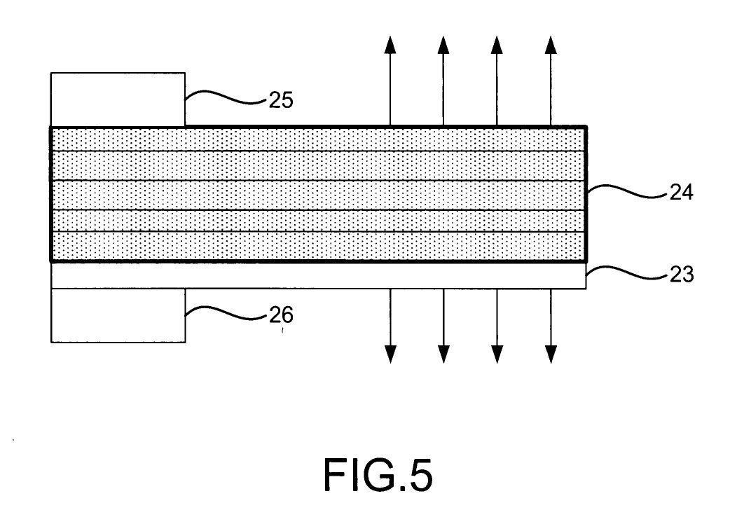

(d) Growing a second metal electrode layer 14: As shown in FIG. 5, a second metal electrode layer 26 is grown beneath the GaN nucleus-site layer 23. Thus, a GaN LED is obtained through a novel method.

In this way, a ZnO buffer layer 22 as a single crystal thin film on the LiAlO₂ substrate is used to successfully grow GaN nucleus-site layer 23, where defect density of the GaN is reduced and light emitting efficiency of a device thus made, like a LED, a laser diode, a field effect transistor, etc., is enhanced.

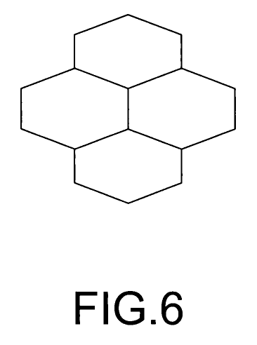

Please refer to FIG. 6, which is a view showing a matched lattice. As shown in the figure, the ZnO buffer layer as a single crystal thin film has a structure changed into a hexagonal cylindrical structure arranged beehive-like. Because the ZnO buffer layer is grown on the LiAlO₂ substrate at first and the lattice mismatch between them is small, a good crystal interface quality is obtained and thus a light emitting efficiency is enhanced.

To sum up, the present invention is a method of fabricating a GaN LED, where a defect density of GaN is reduced to obtain lattice match for a good crystal interface quality and an enhanced light emitting efficiency of a device thus made.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method of fabricating a gallium nitride (GaN) light emitting diode (LED), comprising steps of:
(a) obtaining a substrate of lithium aluminum oxide (LiAlO₂);
(b) growing a GaN nucleus-site layer after growing a zinc oxide (ZnO) buffer layer on said LiAlO₂ substrate to obtain a structure of GaN/ZnO/LiAlO₂ to grow a layer of multiple quantum well (MQW) and a first metal electrode layer;
(c) soaking a structure obtained through the above steps in an acid solution to remove said LiAlO₂ substrate and said ZnO buffer layer through etching; and
(d) growing a second metal electrode layer on said GaN nucleus-site layer opposite to said ZnO buffer layer to obtain a light emitting device of LED.

2. The method according to claim 1,
wherein said substrate is further a substrate of a material selected from a group consisting of lithium gallium oxide (LiGaO₂), lithium silicon oxide (Li₂SiO₃), lithium germanium oxide (LiGeO₃), sodium aluminum oxide (NaAlO₂), sodium germanium oxide (Na₂GeO₃), sodium silicon oxide (Na₂SiO₃), lithium phosphor oxide (Li₃PO₄), lithium arsenic oxide (Li₃AsO₄), lithium vanadium oxide (Li₃VO₄), lithium magnesium germanium oxide (Li₂MgGeO₄), lithium zinc germanium oxide (Li₂ZnGeO₄), lithium cadmium germanium oxide (Li₂CdGeO₄), lithium magnesium silicon oxide (Li₂MgSiO₄), lithium zinc silicon oxide (Li₂ZnSiO₄), lithium cadmium silicon oxide (Li₂CdSiO₄), sodium magnesium germanium oxide (Na₂MgGeO₄), sodium zinc germanium oxide (Na₂ZnGeO₄) and sodium zinc silicon oxide (Na₂ZnSiO₄).

3. The method according to claim 1,
wherein said acid solution is selected from a group consisting of a nitric acid solution, a hydrofluoric acid solution and an acetic acid solution.

4. The method according to claim 1,
wherein said ZnO buffer layer is a single crystal thin film.

5. The method according to claim 1,
wherein said layer of MQW comprises at least one quantum well having a different well width and a different barrier width.

6. The method according to claim 1,
wherein said light emitting device is further selected from a group consisting of a laser diode and a field effect transistor (FET).
